(19) United States
(12) Patent Application Publication
(10) Pub. No.: US 2025/0253828 A1
(43) Pub. Date: Aug. 7, 2025

(54) FILTERING DEVICE AND RADAR SENSOR INCLUDING THE SAME

(71) Applicant: Samsung Electronics Co., Ltd., Suwon-si (KR)

(72) Inventors: Kyunghwan KIM, Suwon-si (KR); Byeongtaek MOON, Suwon-si (KR); Hyunchul PARK, Suwon-si (KR); Sangmin YOO, Suwon-si (KR); Joonhoi HUR, Suwon-si (KR)

(73) Assignee: Samsung Electronics Co., Ltd., Suwon-si (KR)

(21) Appl. No.: 19/015,003

(22) Filed: Jan. 9, 2025

(30) Foreign Application Priority Data
Feb. 6, 2024 (KR) 10-2024-0018400
Jun. 20, 2024 (KR) 10-2024-0080587

(51) Int. Cl. H03H 11/12; G01S 7/35

(52) U.S. Cl. CPC H03H 11/12; G01S 7/354

(57) ABSTRACT

A filtering device for passing a frequency component above a first cutoff frequency in an input signal includes an amplification circuit configured to generate an amplification signal based on the input signal, a first feedback signal, and a second feedback signal, a filter circuit configured to generate an output signal by passing a frequency component above a second cutoff frequency higher than the first cutoff frequency in the amplification signal, and a feedback circuit configured to generate the first feedback signal and the second feedback signal by amplifying the output signal, the filter circuit configured to set the first cutoff frequency based on a first amplification value corresponding to a gain of the amplification circuit and the second cutoff frequency.

### CROSS-REFERENCE TO RELATED APPLICATION

This application is based on and claims priority under 35 U.S.C. § 119 to Korean Patent Application No. 10-2024-0018400, filed on Feb. 6, 2024, and Korean Patent Application No. 10-2024-0080587, filed on Jun. 20, 2024, in the Korean Intellectual Property Office, the disclosures of which are incorporated by reference herein in their entirety.

### BACKGROUND

The inventive concepts relate to filtering devices having a relatively small design area.

An electronic device may include a radar sensor to detect the distance to an object and the speed of the object. The radar sensor may transmit a transmission signal such as a frequency modulated continuous waveform (FMCW) signal to the object and estimate the distance to the object and the speed of the object based on a reflection signal reflected from the object.

The radar sensor may perform signal processing on the reflection signal before estimating the distance to the object and the speed of the object. For example, the radar sensor may filter the reflection signal into a signal with a desired frequency band by passing the reflection signal through a high-pass filter.

In order to accurately sense a distance in units of centimeters through a radar sensor, the cutoff frequency of a high-pass filter included in the radar sensor should be set to a low level of about several tens of kHz. In this case, because the cutoff frequency of the high-pass filter is inversely proportional to the resistance of a resistor and the capacitance of a capacitor included in the high-pass filter, when the cutoff frequency of the high-pass filter is reduced, the size of the capacitor and resistor included in the high-pass filter may increase. That is, when the cutoff frequency of the high-pass filter included in the radar sensor is reduced, the size of the high-pass filter increases, and thus, the total design area of the radar sensor may increase. Thus, it may be advantageous to develop a filter that has a relatively small design area while maintaining the same cutoff frequency.

### SUMMARY

The inventive concepts provide filtering devices having a relatively small design area, for example, resulting in smaller filtering devices.

According to some aspects of the inventive concepts, there is provided a filtering device for passing a frequency component above a first cutoff frequency in an input signal, the filtering device including an amplification circuit configured to generate an amplification signal based on the input signal, a first feedback signal, and a second feedback signal, a filter circuit configured to generate an output signal by passing a frequency component above a second cutoff frequency higher than the first cutoff frequency in the amplification signal, and a feedback circuit configured to generate the first feedback signal and the second feedback signal by amplifying the output signal, the filter circuit configured to set the first cutoff frequency based on a first amplification value corresponding to a gain of the amplification circuit and the second cutoff frequency.

According to some aspects of the inventive concepts, there is provided a filtering device for passing a frequency component above a first cutoff frequency in an input signal, the filtering device including an amplification circuit configured to generate an amplification signal based on the input signal, a first feedback signal, and a second feedback signal, a filter circuit configured to generate an output signal by passing a frequency component above a second cutoff frequency higher than the first cutoff frequency in the amplification signal, and a feedback circuit configured to generate the first feedback signal and the second feedback signal by amplifying the output signal, the filter circuit configured to set the first cutoff frequency based on a gain of the amplification circuit, a gain of the filter circuit, and the second cutoff frequency.

According to some aspects of the inventive concepts, there is provided a radar sensor including a signal generator configured to generate a transmission signal, a transmission amplifier configured to amplify the transmission signal, a transmission antenna configured to radiate the transmission signal, a reception antenna configured to receive, as a reception signal, a reflection signal returned as a result of reflection of the transmission signal from an object, a reception amplifier configured to amplify the reception signal, and a signal processor configured to perform signal processing on the reception signal, the signal processor including a filtering device configured to generate an output signal by passing a frequency component above a first cutoff frequency in an input signal generated based on the reception signal, the filtering device including an amplification circuit configured to generate an amplification signal based on the input signal, a first feedback signal, and a second feedback signal, a filter circuit configured to generate an output signal by passing a frequency component above a second cutoff frequency higher than the first cutoff frequency in the amplification signal, and a feedback circuit configured to generate the first feedback signal and the second feedback signal by amplifying the output signal, the filtering device configured to set the first cutoff frequency based on a first amplification value corresponding to a gain of the amplification circuit and the second cutoff frequency.

### BRIEF DESCRIPTION OF THE DRAWINGS

Example embodiments will be more clearly understood from the following detailed description taken in conjunction with the accompanying drawings in which:

FIG. 1 is a block diagram illustrating a radar sensor according to some example embodiments;

FIG. 2 is a block diagram illustrating a signal processor included in a radar sensor according to some example embodiments;

FIG. 3 is a block diagram illustrating a filtering device included in a radar sensor according to some example embodiments;

FIG. 4 is a circuit diagram illustrating an example of an amplification circuit of a filtering device according to some example embodiments;

FIG. 5 is a circuit diagram illustrating an example of a filter circuit of a filtering device according to some example embodiments;

FIG. 6 is a circuit diagram illustrating an example of a feedback circuit of a filtering device according to some example embodiments;

FIG. 7 is a circuit diagram illustrating another example of an amplification circuit of a filtering device according to some example embodiments;

FIG. 8 is a circuit diagram illustrating another example of a feedback circuit of a filtering device according to some example embodiments;

FIG. 9 is a block diagram illustrating a computing device including a radar sensor according to some example embodiments; and

FIG. 10 is a block diagram illustrating an autonomous driving system including a radar sensor according to some example embodiments.

### DETAILED DESCRIPTION

Hereinafter, example embodiments will be described in detail with reference to the accompanying drawings.

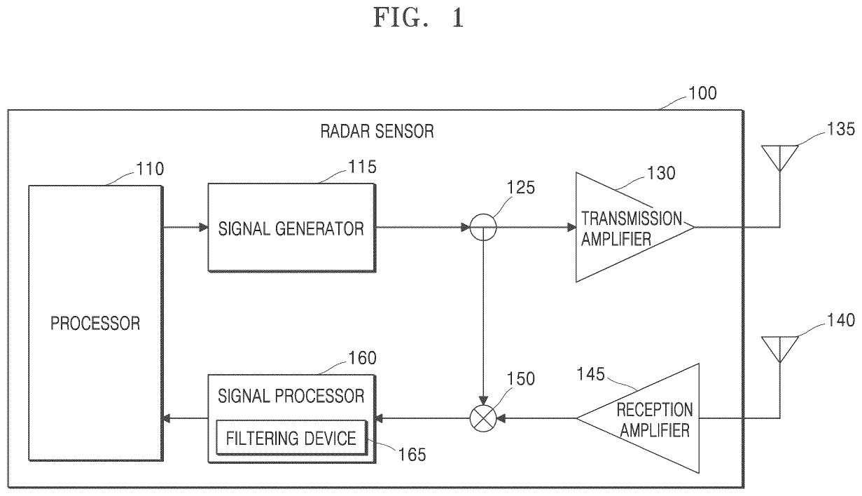

FIG. 1 is a block diagram illustrating a radar sensor according to some example embodiments.

Referring to FIG. 1, a radar sensor 100 according to some example embodiments may include a processor 110, a signal generator 115, a signal distributor 125, a transmission amplifier 130, a transmission antenna 135, a reception antenna 140, a reception amplifier 145, a reception frequency converter 150, and a signal processor 160.

The radar sensor 100 may detect a distance to an object in the outside thereof and a speed of the object. The radar sensor 100 may generate a signal, radiate the signal to the outside, receive a reflection signal returned as a result of reflection of the radiated signal from the object, and estimate the distance to the object and the speed of the object based on the reflection signal.

The processor 110 may control an overall operation of the radar sensor 100. The processor 110 may transmit a control signal to the signal generator 115 to generate a transmission signal and may predict the distance to the object and the speed of the object based on a signal output from the signal processor 160.

The signal generator 115 may generate a transmission signal based on the control signal received from the processor 110. In some example embodiments, the transmission signal may be a frequency modulated continuous waveform (FMCW) signal generated based on a preset (or, alternatively, desired, determined, selected, etc.) frequency modulation pattern. The FMCW signal generated by the signal generator 115 may represent a waveform in which a carrier frequency gradually increases in some time intervals and gradually decreases in other time intervals.

The signal generator 115 may include a voltage controlled oscillator (VCO) circuit for generating various oscillation frequencies, and a phase locked loop (PLL) circuit for improving the stability of the output frequency of the VCO circuit.

The signal distributor 125 may receive the transmission signal generated by the signal generator 115. The signal distributor 125 may divide the transmission signal and transmit the resulting signals to the transmission amplifier 130 and the reception frequency converter 150.

The transmission amplifier 130 may amplify the transmission signal received from the signal distributor 125. The transmission amplifier 130 may amplify the transmission signal and transmit the resulting signal to the transmission antenna 135.

The transmission antenna 135 may radiate the amplified transmission signal received from the transmission amplifier 130. FIG. 1 illustrates some example embodiments in which the radar sensor 100 includes one transmission antenna 135; however, the inventive concepts are not limited thereto and the radar sensor 100 may include one or more transmission antennas 135. Each of the one or more transmission antennas 135 may radiate a transmission signal in a time interval that is managed by the transmission antenna itself according to the time division method.

The reception antenna 140 may receive, as a reception signal, a reflection signal returned as a result of reflection of the radiated transmission signal from the object. FIG. 1 illustrates some example embodiments in which the radar sensor 100 includes one reception antenna 140; however, the inventive concepts are not limited thereto and the radar sensor 100 may include one or more reception antennas 140.

The reception amplifier 145 may amplify the reception signal received through the reception antenna 140. The reception amplifier 145 may amplify the reception signal and transmit the resulting signal to the reception frequency converter 150.

The reception frequency converter 150 may receive the reception signal amplified by the reception amplifier 145 and the transmission signal distributed by the signal distributor 125. The reception frequency converter 150 may modulate the reception signal into a baseband signal by multiplying the transmission signal received from the signal distributor 125 by the reception signal. The reception frequency converter 150 may transmit the modulated reception signal to the signal processor 160.

The signal processor 160 may perform signal processing on the modulated reception signal received through the reception frequency converter 150. The signal processor 160 may perform processing such as high-frequency filtering, low-frequency filtering, variable-gain amplification, and/or offset removal on the reception signal.

In some example embodiments, the signal processor 160 may include a filtering device 165 that generates an output signal by passing a frequency component above a first cutoff frequency in an input signal generated based on the reception signal.

The filtering device 165 may include an amplification circuit, a filter circuit, and a feedback circuit. In this case, the first cutoff frequency may be set based on a first amplification value corresponding to a gain of the amplification circuit and a second cutoff frequency that is a cutoff frequency of the filter circuit.

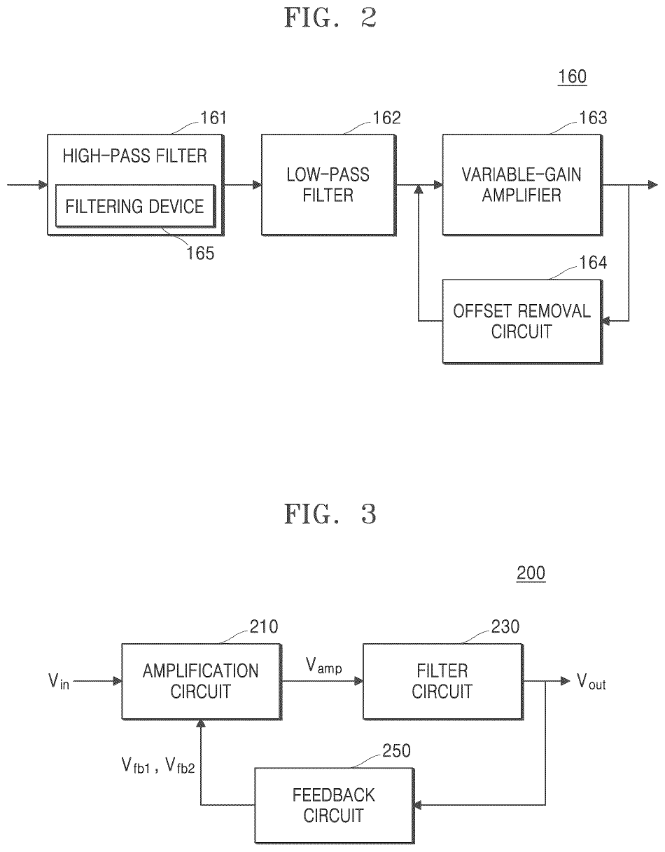

A more detailed structure of the signal processor 160 will be described below with reference to FIG. 2, and a more detailed structure and operation of the filtering device 165 will be described below with reference to FIG. 3 and the following figures.

FIG. 2 is a block diagram illustrating a signal processor included in a radar sensor according to some example embodiments.

Referring to FIG. 2, the signal processor 160 included in the radar sensor 100 according to some example embodiments may include a high-pass filter 161, a low-pass filter 162, a variable-gain amplifier 163, and an offset removal circuit 164.

The high-pass filter 161 may receive the reception signal amplified by the reception amplifier 145 and modulated by the reception frequency converter 150. The high-pass filter 161 may pass a frequency component above a preset (or, alternatively, desired, determined, selected, etc.) cutoff frequency in an input signal.

The cutoff frequency of the high-pass filter 161 may be set to a low level of about several tens of kHz (for example, about or exactly 10 kHz, about or exactly 20 kHz, about or exactly 30 kHz, about or exactly 40 kHz, about or exactly 50 kHz, about or exactly 60 kHz, about or exactly 70 kHz, about or exactly 80 kHz, about or exactly 90 kHz, about or exactly 100 kHz). In this case, the cutoff frequency of the high-pass filter may be inversely proportional to the resistance of a resistor and the capacitance of a capacitor included in the high-pass filter. Thus, when the cutoff frequency of the high-pass filter is reduced, the size of the resistor and capacitor included in the high-pass filter may increase and thus the design area of the high-pass filter may increase.

In some example embodiments, the high-pass filter 161 may include a filtering device 165. The filtering device 165 may generate an output signal by passing a frequency component above a first cutoff frequency in an input signal generated based on a reception signal. The filtering device 165 may include an amplification circuit, a filter circuit, and a feedback circuit. In this case, the first cutoff frequency may be set based on a first amplification value corresponding to a gain of the amplification circuit and a second cutoff frequency that is a cutoff frequency of the filter circuit. Accordingly, the filtering device 165 having a relatively small design area while having the same cutoff frequency may be provided, and a more detailed structure and operation principle will be described below with reference to FIG. 3 and the following figures.

The low-pass filter 162 may receive a signal that has passed through the high-pass filter 161. The low-pass filter 162 may pass a frequency component below a preset (or, alternatively, desired, determined, selected, etc.) cutoff frequency in the received signal. The cutoff frequency of the low-pass filter 162 may be higher than the cutoff frequency of the high-pass filter 161. By sequentially passing the high-pass filter 161 and the low-pass filter 162 as such, a component of a desired frequency band may be extracted from the reception signal.

The variable-gain amplifier 163 may receive a signal that has passed through the low-pass filter 162. The variable-gain amplifier 163 may amplify the signal that has passed through the low-pass filter 162 to have a target signal strength.

The offset removal circuit 164 may receive a signal that has passed through the variable-gain amplifier 163. The offset removal circuit 164 may be located on the feedback path of the variable-gain amplifier 163. The offset removal circuit 164 may remove a direct current offset caused by, for example, an error in an oscillator, a switching element, and/or the like inside the radar sensor 100, from the signal that has passed through the variable-gain amplifier 163.

FIG. 3 is a block diagram illustrating a filtering device included in a radar sensor according to some example embodiments.

Referring to FIG. 3, a filtering device 200 according to some example embodiments may include an amplification circuit 210, a filter circuit 230, and a feedback circuit 250. In this case, the filtering device 200 of FIG. 3 may be used as the filtering device 165 of FIG. 2.

The filtering device 200 may receive an input signal Vᵢₙ. The input signal Vᵢₙ may be a signal input to the signal processor 160 of the radar sensor 100 and may be a reception signal amplified by the reception amplifier 145 and modulated by the reception frequency converter 150. The filtering device 200 may generate an output signal by passing a frequency component above a first cutoff frequency in the input signal Vᵢₙ generated based on the reception signal.

The amplification circuit 210 may receive the input signal Vᵢₙ. Also, the amplification circuit 210 may receive a first feedback signal V_{fb1} and a second feedback signal V_{fb2}. The first feedback signal V_{fb1} and the second feedback signal V_{fb2} may be signals generated through the feedback circuit 250.

The amplification circuit 210 may generate an amplification signal Vₐₘₚ based on the input signal Vᵢₙ, the first feedback signal V_{fb1}, and the second feedback signal V_{fb2}. More particularly, the amplification circuit 210 may subtract the first feedback signal V_{fb1} from the input signal Vᵢₙ, amplify the subtraction result by a first amplification value, and subtract the second feedback signal V_{fb2} from the amplification result to generate the amplification signal Vₐₘₚ. This may be represented as Equation 1 below.

$${V}_{a m p} = A ( {V}_{i n} - {V}_{fb 1} ) - {V}_{fb 2} \qquad [ Equation 1 ]$$

In Equation 1, “A” may be the first amplification value.

The filter circuit 230 may generate an output signal Vₒᵤₜ by passing a frequency component above a second cutoff frequency higher than the first cutoff frequency in the amplification signal Vₐₘₚ. In other words, the filter circuit 230 may operate as a filter having a higher cutoff frequency than the filtering device 200. The order of the filter circuit 230 may be an nth order (where “n” is a natural number greater than or equal to 1). However, for the convenience of descriptions, a case where the order of the filter circuit 230 is a second order will be mainly described, and a case where the order of the filter circuit 230 is an nth order will be additionally described. When the order of the filter circuit 230 is a second order, a transfer function of the filter circuit 230 may be represented as Equation 2 below.

$$\frac{{V}_{out}}{{V}_{a m p}} = \frac{{s}^{2}}{{s}^{2} + \frac{{ω}_{0 , 2}}{{Q}_{2}} s + {ω}_{0 , 2}^{2}} \qquad [ Equation 2 ]$$

In Equation 2, “s” may be a Laplace variable, Q₂ may be a quality factor of the filter circuit 230, and ω_{0,2} may be the second cutoff frequency.

The feedback circuit 250 may amplify the output signal Vₒᵤₜ to generate the first feedback signal V_{fb1} and the second feedback signal V_{fb2}. More particularly, the feedback circuit 250 may amplify the output signal Vₒᵤₜ by a second amplification value to generate the first feedback signal V_{fb1} and may amplify the output signal Vₒᵤₜ by a third amplification value to generate the second feedback signal V_{fb2}. This may be represented as Equation 3 and Equation 4 below.

$${V}_{fb 1} = {BV}_{out} \qquad [ Equation 3 ]$$

$${V}_{fb 2} = C {V}_{out} \qquad [ Equation 4 ]$$

In Equation 3, “B” may be the second amplification value, and in Equation 4, “C” may be the third amplification value.

Based on Equation 1 to Equation 4 described above, a transfer function of the filtering device 200 may be obtained as Equation 5 below.

$$\frac{{V}_{out}}{{V}_{i n}} = \frac{A}{A C + B + 1} \times \frac{{s}^{2}}{{s}^{2} + \frac{\frac{{ω}_{0 , 2}}{{Q}_{2}} s + {ω}_{0 , 2}^{2}}{A C + B + 1}} \qquad [ Equation 5 ]$$

In this case, the first cutoff frequency that is the cutoff frequency of the filtering device 200 may be represented as Equation 6 below.

$${ω}_{0 , 1} = \frac{{ω}_{0 , 2}}{\sqrt{A C + B + 1}} \qquad [ Equation 6 ]$$

In Equation 6, ω_{0,1} may be the first cutoff frequency.

Referring to Equation 6, in some example embodiments, the first cutoff frequency ω_{0,1} may be set based on the first amplification value A corresponding to the gain of the amplification circuit 210 and the second cutoff frequency ω_{0,2}. More particularly, the first cutoff frequency ω_{0,1} may be set based on the first amplification value A, the second amplification value B, the third amplification value C, and the second cutoff frequency ω_{0,2}. That is, by using the filter circuit 230 having the second cutoff frequency ω_{0,2} higher than the first cutoff frequency ω_{0,1} and by adjusting the first amplification value A, the second amplification value B, and the third amplification value C through the amplification circuit 210 and the feedback circuit 250, the cutoff frequency of the filtering device 200 may be set to the target first cutoff frequency ω_{0,1}.

As such, compared to using the filtering device 200 including only the filter circuit 230 having the first cutoff frequency ω_{0,1}, when using the filter circuit 230 having the second cutoff frequency ω_{0,2} that is a relatively high cutoff frequency (for example, higher than the first cutoff frequency ω_{0,1}), the size of the resistor and capacitor included in the filter circuit 230 may be reduced to reduce the design area. In this case, when using a filter circuit 230 having the second cutoff frequency ω_{0,2}, the increase in the design area caused by the additional inclusion of the amplification circuit 210 and the feedback circuit 250 may be much smaller than the decrease in the design area caused by the decrease in the size of the resistor and capacitor of the filter circuit 230. For example, according to some example embodiments, there may be an increase in size, reliability, operating parameters (e.g., temperature), speed, accuracy, and/or power efficiency of the filtering device based on the above methods. Therefore, the improved devices and methods overcome the deficiencies of the conventional devices and methods while reducing a size thereof, resource consumption, and/or improving data accuracy, operating parameters, and resource allocation (e.g., latency). Further, there is an improvement in user experience in the device by providing the improved process.

Also, in Equation 5, the gain of the filtering device 200 may be equal to A/(AC+B+1). Thus, in some example embodiments, the gain of the filtering device 200 may be set based on the first amplification value A, the second amplification value B, and the third amplification value C. That is, the gain of the filtering device 200 may be set to a target value by adjusting the first amplification value A, the second amplification value B, and the third amplification value C.

In this case, when the second amplification value is set to −1, Equation 5 may be represented as Equation 7 below, and Equation 6 may be represented as Equation 8 below.

$$\frac{{V}_{out}}{{V}_{i n}} = \frac{1}{C} \times \frac{{s}^{2}}{{s}^{2} + \frac{\frac{{ω}_{0 , 2}}{{Q}_{2}} s + {ω}_{0 , 2}^{2}}{A C}} \qquad [ Equation 7 ]$$

$${ω}_{0 , 1} = \frac{{ω}_{0 , 2}}{\sqrt{A C}} \qquad [ Equation 8 ]$$

Referring to Equation 7, in some example embodiments, when the second amplification value B is −1, the gain of the filtering device 200 may be set based on the third amplification value C.

Also, referring to Equation 8, in some example embodiments, when the second amplification value B is −1, the first cutoff frequency ω_{0,1} may be proportional to the second cutoff frequency ω_{0,2} and may be set based on the first amplification value A and the third amplification value C.

That is, when the second amplification value B is −1, the gain of the filtering device 200 may be adjusted by adjusting the third amplification value C. Next, the first cutoff frequency ω_{0,1} may be adjusted by adjusting the second cutoff frequency ω_{0,2} and the first amplification value A.

When the filter circuit 230 is an nth-order filter, the first cutoff frequency ω_{0,1} may be represented as Equation 9 below.

$${ω}_{0 , 1} ∝ \frac{{ω}_{0 , 2}}{\sqrt[n]{A C + B + 1}} \qquad [ Equation 9 ]$$

Referring to Equation 9, in some example embodiments, the first cutoff frequency ω_{0,1} may be set to be inversely proportional to the nth root of the first amplification value A. In this case, when the second amplification value is set to −1, the first cutoff frequency ω_{0,1} may be set to be inversely proportional to the nth root of the first amplification value A and inversely proportional to the nth root of the third amplification value C.

As described above with reference to FIG. 3, when connecting and using the filter circuit 230 having the second cutoff frequency ω_{0,2} that is a relatively high cutoff frequency, the amplification circuit 210, and the feedback circuit 250, the filtering device 200 having the same cutoff frequency and the same gain may be implemented with a relatively small design area, compared to using only the filter circuit 230 having the first cutoff frequency ω_{0,1} that is a relatively low cutoff frequency.

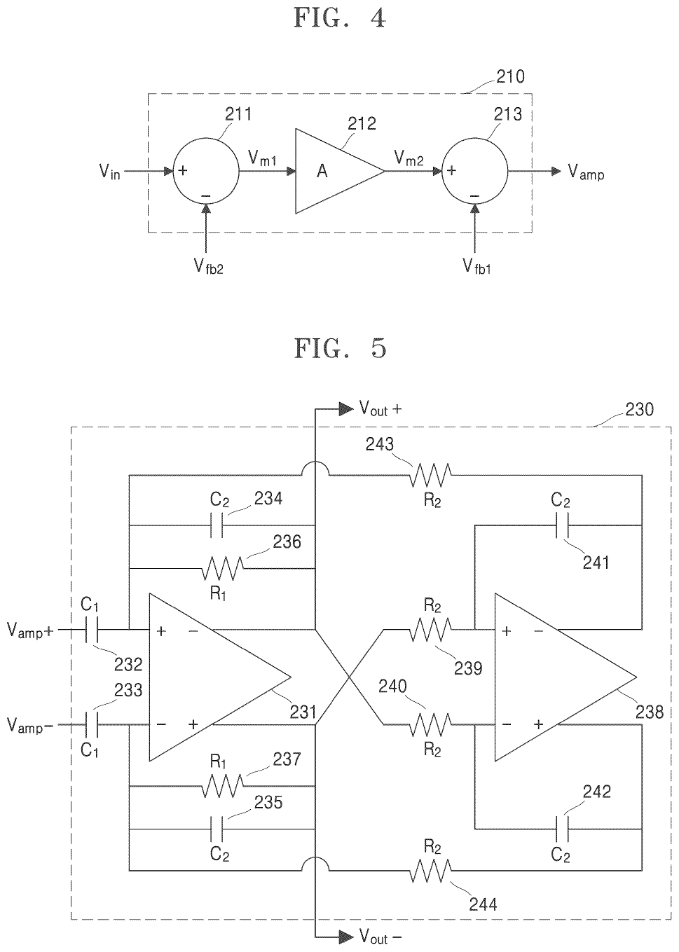

FIG. 4 is a circuit diagram illustrating an example of an amplification circuit of a filtering device according to some example embodiments.

Referring to FIG. 4, in some example embodiments, the amplification circuit 210 may include a first subtractor 211, a first amplifier 212, and a second subtractor 213.

The first subtractor 211 may receive the input signal Vᵢₙ and the second feedback signal V_{fb2}. The first subtractor 211 may generate a first intermediate signal Vₘ₁ by subtracting the second feedback signal V_{fb2} from the input signal Vᵢₙ.

The first amplifier 212 may receive the first intermediate signal Vₘ₁. The first amplifier 212 may generate a second intermediate signal Vₘ₂ by amplifying the first intermediate signal Vₘ₁ by the first amplification value A.

The second subtractor 213 may receive the second intermediate signal Vₘ₂ and the first feedback signal V_{fb1}. The second subtractor 213 may generate an amplification signal Vₐₘₚ by subtracting the first feedback signal V_{fb1} from the second intermediate signal Vₘ₂.

That is, the amplification circuit 210 may be implemented as in FIG. 4, and an operation such as Equation 1 may be performed through the amplification circuit 210.

FIG. 5 is a circuit diagram illustrating an example of a filter circuit of a filtering device according to some example embodiments.

Referring to FIG. 5, the filter circuit 230 may include a plurality of amplifiers 231 and 238, a plurality of resistors 236, 237, 239, 240, 243, and 244, and a plurality of capacitors 232, 233, 234, 235, 241, and 242. In some example embodiments of FIG. 5, the filter circuit 230 may have a second order and may be a modified structure of a Tow-Thomas filter designed in a differential mode. However, the inventive concepts are not limited thereto, and a filter circuit 230 different from that of FIG. 5 may be used as the filter circuit 230.

The filter circuit 230 may receive a pair of amplification signals Vₐₘₚ+ and Vₐₘₚ−. The filter circuit 230 may generate a pair of output signals Vₒᵤₜ+ and Vₒᵤₜ− by passing a component above the second cutoff frequency ω_{0,2} higher than the first cutoff frequency ω_{0,1} in the pair of amplification signals Vₐₘₚ+ and Vₐₘₚ−.

The pair of amplification signals Vₐₘₚ+ and Vₐₘₚ− may be input to a pair of capacitors 232 and 233 respectively. In this case, the capacitance of the pair of capacitors 232 and 233 may be a first capacitance C₁.

The pair of capacitors 232 and 233 may be connected to the input terminal of the amplifier 231.

A pair of capacitors 234 and 235 and a pair of resistors 236 and 237 may be connected in parallel between the input terminal and the output terminal of the amplifier 231. In this case, the capacitance of the pair of capacitors 234 and 235 may be a second capacitance C₂, and the resistance of the pair of resistors 236 and 237 may be a first resistance R₁.

The pair of output signals Vₒᵤₜ+ and Vₒᵤₜ− may be output through the output terminal of the amplifier 231.

The output terminal of the amplifier 231 may be connected to a pair of resistors 239 and 240. In this case, the resistance of the pair of resistors 239 and 240 may be a second resistance R₂.

The pair of resistors 239 and 240 may be connected to the input terminal of the amplifier 238.

A pair of capacitors 241 and 242 may be connected between the input terminal and the output terminal of the amplifier 238. In this case, the capacitance of the pair of capacitors 241 and 242 may be the second capacitance C₂.

A pair of resistors 243 and 244 may be connected between the output terminal of the amplifier 238 and the input terminal of the amplifier 231. In this case, the resistance of the pair of resistors 243 and 244 may be the second resistance R₂.

The second cutoff frequency ω_{0,2} that is the cutoff frequency of the filter circuit 230 may be 1/(R₂C₂). Thus, when the second cutoff frequency ω_{0,2} increases, because the second resistance R₂ and the second capacitance C₂ decrease, the size of the resistor and capacitor included in the filter circuit 230 may be reduced. Accordingly, the design area of the filtering device 200 may be reduced.

The gain of the filter circuit 230 may be C₁/C₂. In some example embodiments, by setting the first capacitance C₁ and the second capacitance C₂ to be equal to each other, the gain of the filter circuit 230 may be set to 1.

In some example embodiments, the first capacitance C₁ and the second capacitance C₂ may be set to be different from each other to adjust the gain of the filter circuit 230 to adjust the total gain of the filtering device 200. The transfer function of the filtering device 200, in consideration of the gain of the filter circuit 230, may be represented as Equation 10 below.

$$\frac{{V}_{out}}{{V}_{i n}} = \frac{\frac{{C}_{1}}{{C}_{2}} A}{\frac{{C}_{1}}{{C}_{2}} A C + B + 1} \times \frac{{s}^{2}}{{s}^{2} + \frac{\frac{{ω}_{0 , 2}}{{Q}_{2}} s + {ω}_{0 , 2}^{2}}{\frac{{C}_{1}}{{C}_{2}} A C + B + 1}} \qquad [ Equation 10 ]$$

In this case, the first cutoff frequency ω_{0,1} that is the cutoff frequency of the filtering device 200 may be represented as Equation 11 below.

$${ω}_{0 , 1} = \frac{{ω}_{0 , 2}}{\sqrt{\frac{{C}_{1}}{{C}_{2}} A C + B + 1}} \qquad [ Equation 11 ]$$

That is, in some example embodiments, the first cutoff frequency ω_{0,1} may be set based on the first amplification value A that is the gain of the amplification circuit 210, the gain C₁/C₂ of the filter circuit 230, and the second cutoff frequency ω_{0,2}. More particularly, the first cutoff frequency ω_{0,1} may be set based on the first amplification value A, the gain C₁/C₂ of the filter circuit 230, the second amplification value B, the third amplification value C, and the second cutoff frequency ω_{0,2.}

In this case, when the second amplification value B is −1, the first cutoff frequency ω_{0,1} may be proportional to the second cutoff frequency ω_{0,2} and may be set based on the first amplification value A, the gain C₁/C₂ of the filter circuit 230, the third amplification value C, and the second cutoff frequency ω_{0,2}.

Also, referring to Equation 10, the gain of the filtering device 200 may be set based on the first amplification value A, the gain C₁/C₂ of the filter circuit 230, the second amplification value B, and the third amplification value C.

In this case, when the second amplification value B is −1, the gain of the filtering device 200 may be set based on the third amplification value C.

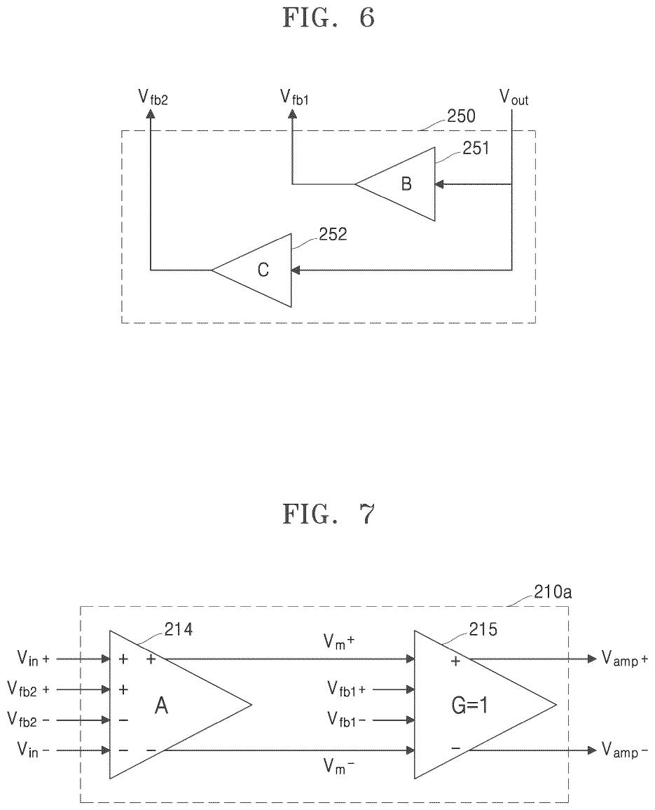

FIG. 6 is a circuit diagram illustrating an example of a feedback circuit of a filtering device according to some example embodiments.

Referring to FIG. 6, in some example embodiments, the feedback circuit 250 may include a second amplifier 251 and a third amplifier 252. In this case, the feedback circuit 250 of FIG. 6 may be used together with the amplification circuit 210 of FIG. 4.

The second amplifier 251 may receive the output signal Vₒᵤₜ. The second amplifier 251 may generate the first feedback signal V_{fb1} by amplifying the output signal Vₒᵤₜ by the second amplification value B.

The third amplifier 252 may receive the output signal Vₒᵤₜ. The third amplifier 252 may generate the second feedback signal Vₘ₂ by amplifying the output signal Vₒᵤₜ by the third amplification value C.

FIG. 7 is a circuit diagram illustrating another example of an amplification circuit of a filtering device according to some example embodiments.

Referring to FIG. 7, in some example embodiments, the amplification circuit 210a may include a first amplifier 214 and a second amplifier 215. In this case, the amplification circuit 210a of FIG. 7 may have a structure designed in a differential mode.

The first amplifier 214 may receive a pair of input signals Vᵢₙ+ and Vᵢₙ− and a pair of second feedback signals V_{fb2}+ and V_{fb2}−. The first amplifier 214 may generate a pair of intermediate signals Vₘ+ and Vₘ− by amplifying, by the first amplification value A, the result of subtracting the pair of second feedback signals V_{fb2}+ and V_{fb2}− from the pair of input signals Vᵢₙ+ and Vᵢₙ−.

The second amplifier 215 may receive a pair of intermediate signals Vₘ+ and Vₘ− and a pair of first feedback signals V_{fb1}+ and V_{fb1}−. The second amplifier 215 may generate a pair of amplification signals Vₐₘₚ+ and Vₐₘₚ− by amplifying, by a fourth amplification value G, the result of subtracting the pair of first feedback signals V_{fb1}+ and V_{fb1}− from the pair of intermediate signals Vₘ+ and Vₘ−. In this case, when the fourth amplification value G is 1, the second amplifier 215 may generate the pair of amplification signals Vₐₘₚ+ and Vₐₘₚ− by subtracting the pair of first feedback signals V_{fb1}+ and V_{fb1}− from the pair of intermediate signals Vₘ+ and Vₘ−.

That is, the amplification circuit 210a may be implemented as in FIG. 7, and an operation such as Equation 1 may be performed through the amplification circuit 210a.

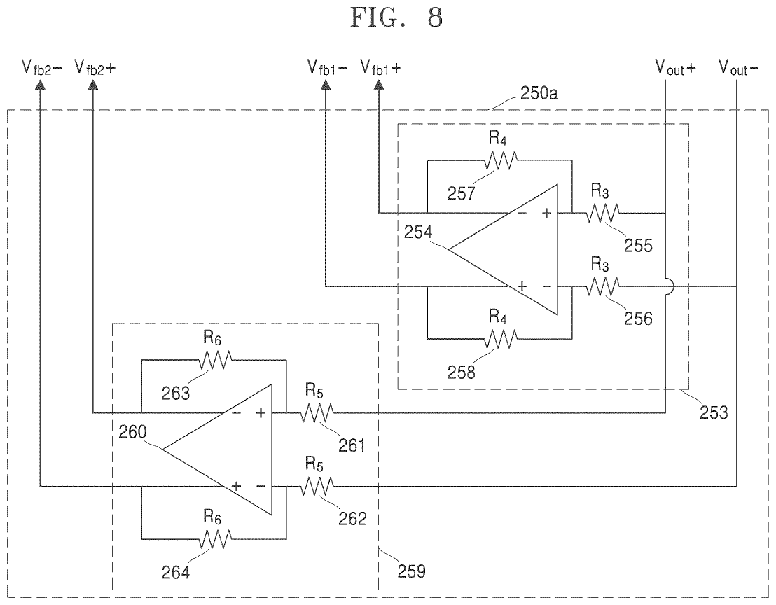

FIG. 8 is a circuit diagram illustrating another example of a feedback circuit of a filtering device according to some example embodiments.

Referring to FIG. 8, in some example embodiments, the feedback circuit 250a may include a first feedback amplification circuit 253 and a second feedback amplification circuit 259. In this case, the feedback circuit 250a of FIG. 8 may have a structure designed in a differential mode and may be used together with the amplification circuit 210 of FIG. 7.

The first feedback amplification circuit 253 may include an amplifier 254 and a plurality of resistors 255, 256, 257, and 258.

The first feedback amplification circuit 253 may receive the pair of output signals Vₒᵤₜ+ and Vₒᵤₜ−. The pair of output signals Vₒᵤₜ+ and Vₒᵤₜ− may be input to a pair of resistors 255 and 256 respectively. In this case, the resistance of the pair of resistors 255 and 256 may be a third resistance R₃. The pair of resistors 255 and 256 may be connected to the input terminal of the amplifier 254.

A pair of resistors 257 and 258 may be connected between the input terminal and the output terminal of the amplifier 254. In this case, the resistance of the pair of resistors 257 and 258 may be a fourth resistance R₄. A pair of first feedback signals V_{fb1}+ and V_{fb1}− may be output through the output terminal of the amplifier 254. The second amplification value B that is the gain of the first feedback amplification circuit 253 may be −R₄/R₃.

The second feedback amplification circuit 259 may include an amplifier 260 and a plurality of resistors 261, 262, 263, and 264.

The second feedback amplification circuit 259 may receive the pair of output signals Vₒᵤₜ+ and Vₒᵤₜ−. The pair of output signals Vₒᵤₜ+ and Vₒᵤₜ− may be input to a pair of resistors 261 and 262 respectively. In this case, the resistance of the pair of resistors 261 and 262 may be a fifth resistance R₅. The pair of resistors 261 and 262 may be connected to the input terminal of the amplifier 260.

A pair of resistors 263 and 264 may be connected between the input terminal and the output terminal of the amplifier 260. In this case, the resistance of the pair of resistors 263 and 264 may be a sixth resistance R₆. A pair of second feedback signals V_{fb2}+ and V_{fb2}− may be output through the output terminal of the amplifier 260. The third amplification value C that is the gain of the second feedback amplification circuit 259 may be −R₆/R₅.

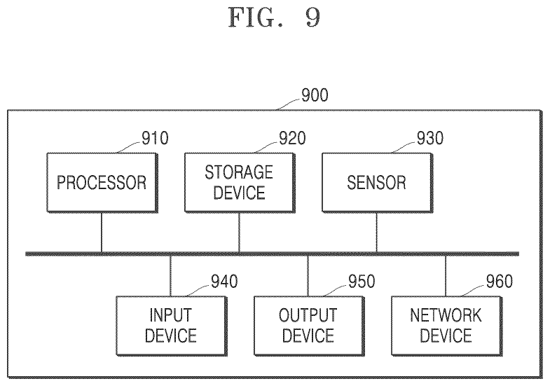

FIG. 9 is a block diagram illustrating a computing device including a radar sensor according to some example embodiments.

Referring to FIG. 9, a computing device 900 may perform operations and functions for detecting a distance to an object in the outside thereof and a speed of the object. The computing device 900 may be used in an autonomous driving system, a flight radar system, a driver assistance system, an object recognition system, a surveillance/security system, and the like. The computing device 900 may be mounted and operated, for example, in an image processing device, a radar device, a smartphone, a wearable device, a tablet computer, a netbook, a laptop, a desktop, a head mounted display (HMD), an autonomous vehicle, a smart vehicle, and the like.

The computing device 900 may include a processor 910, a storage device 920, a sensor 930, an input device 940, an output device 950, and a network device 960. The processor 910, the storage device 920, the sensor 930, the input device 940, the output device 950, and the network device 960 may communicate with each other through a communication bus.

The processor 910 may execute functions and instructions for execution in the computing device 900. For example, the processor 910 may process instructions stored in the storage device 920.

The storage device 920 may store information or data necessary for the processing operation of the processor 910. The storage device 920 may store instructions for execution by the processor 910. The storage device 920 may include a computer-readable storage medium, such as random access memories (RAMs), dynamic random access memories (DRAMs), static random access memories (SRAMs), magnetic hard disks, optical disks, flash memories, or electrically programmable memories (EPROMs), or other types of computer-readable storage mediums known in the art.

The sensor 930 may include one or more sensors. The sensor 930 may include a radar sensor, an image sensor, and/or the like. In this case, the radar sensor included in the sensor 930 may be implemented as the radar sensor 100 according to some example embodiments described above with reference to FIGS. 1 to 8.

The input device 940 may receive an input from a user through a tactile, video, audio, and/or touch input. The input device 940 may include a keyboard, a mouse, a touch screen, a microphone, and/or any other device capable of detecting an input from the user and transmitting the detected input.

The output device 950 may provide the output of the computing device 900 to the user through a visual, auditory, or tactile manner. For example, the output device 950 may include a liquid crystal display, a light emitting diode (LED) display, a touch screen, a speaker, a vibration generating device, or any other device capable of providing an output to the user. In some example embodiments, the output device 950 may provide the result reflecting the position information of the object estimated by the processor 910, by using one or more of visual information, auditory information, and haptic information.

The network device 960 may communicate with an external device through a wired or wireless network. For example, the network device 960 may communicate with an external device by using a wired communication method or a wireless communication method such as Bluetooth, WiFi, 3^{rd} Generation (3G), or Long Term Evolution (LTE).

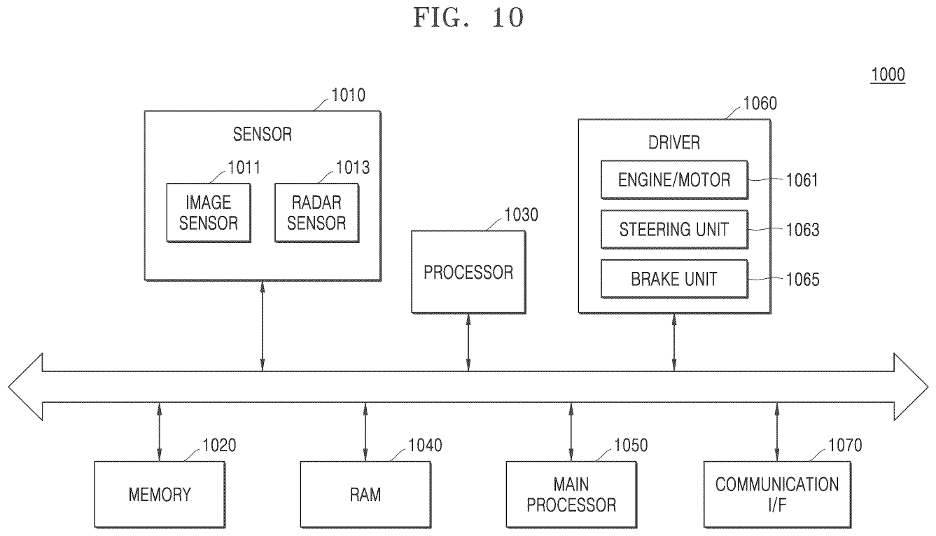

FIG. 10 is a block diagram illustrating an autonomous driving system including a radar sensor according to some example embodiments.

Referring to FIG. 10, an autonomous driving device 1000 may include a sensor 1010, a memory 1020, a processor 1030, a RAM 1040, a main processor 1050, a driver 1060, and a communication interface 1070, and the components of the autonomous driving device 1000 may be communicatively connected to each other through a bus.

The sensor 1010 may include a plurality of sensors for generating information about the surrounding environment of the autonomous driving device 1000. For example, the sensor 1010 may include a plurality of sensors for receiving an image signal about the surrounding environment of the autonomous driving device 1000 and outputting the received image signal as an image. The sensor 1010 may include an image sensor 1011 such as a charge coupled device (CCD) or a complementary metal oxide semiconductor (CMOS), a radar sensor 1013, and/or the like. In some example embodiments, the image sensor 1011 may generate a front image of the autonomous driving device 1000 and provide the front image to the processor 1030. In some example embodiments, the radar sensor 1013 may detect a distance to an object in the outside thereof and a speed of the object. In this case, the radar sensor 1013 may be implemented as the radar sensor 100 according to some example embodiments described above with reference to FIGS. 1 to 8.

The memory 1020 may be a storage place for storing data and may store, for example, various data generated during the operation execution process of the main processor 1050 and the processor 1030.

The processor 1030 may process various operations associated with the sensor 1010.

The main processor 1050 may control an overall operation of the autonomous driving device 1000. For example, the main processor 1050 may control the function of the processor 1030 by executing programs stored in the RAM 1040. The RAM 1040 may temporarily store programs, data, applications, or instructions.

Also, the main processor 1050 may control the operation of the autonomous driving device 1000 based on the operation result of the processor 1030. As some example embodiments, the main processor 1050 may receive information about the position and speed of the target from the processor 1030 and control the operation of the driver 1060 based on the received information about the position and speed.

The driver 1060 may be a component for driving the autonomous driving device 1000 and may include an engine/motor 1061, a steering unit 1063, and a brake unit 1065. In some example embodiments, the driver 1060 may adjust the propulsion, braking, speed, direction, and the like of the autonomous driving device 1000 by using the engine/motor 1061, the steering unit 1063, and the brake unit 1065 under the control by the processor 1030.

The communication interface 1070 may perform communication with an external device by using a wired or wireless communication method. For example, the communication interface 1070 may perform communication by using a wired communication method such as Ethernet or may perform communication by using a wireless communication method such as WiFi and/or Bluetooth.

Any or all of the elements described with reference to the figures may communicate with any or all other elements described with reference to figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While the inventive concepts have been particularly shown and described with reference to example embodiments thereof, it will be understood that various changes in form and details may be made therein without departing from the spirit and scope of the following claims.

1. A filtering device for passing a frequency component above a first cutoff frequency in an input signal, the filtering device comprising:
an amplification circuit configured to generate an amplification signal based on the input signal, a first feedback signal, and a second feedback signal;
a filter circuit configured to generate an output signal by passing a frequency component above a second cutoff frequency higher than the first cutoff frequency in the amplification signal; and
a feedback circuit configured to generate the first feedback signal and the second feedback signal by amplifying the output signal,
the filter circuit configured to set the first cutoff frequency based on a first amplification value corresponding to a gain of the amplification circuit and the second cutoff frequency.

2. The filtering device of claim 1, wherein the amplification circuit comprises:
a first subtractor configured to generate a first intermediate signal by subtracting the second feedback signal from the input signal;
a first amplifier configured to generate a second intermediate signal by amplifying the first intermediate signal by the first amplification value; and
a second subtractor configured to generate the amplification signal by subtracting the first feedback signal from the second intermediate signal.

3. The filtering device of claim 1, wherein the feedback circuit comprises:
a second amplifier configured to generate the first feedback signal by amplifying the output signal by a second amplification value; and
a third amplifier configured to generate the second feedback signal by amplifying the output signal by a third amplification value.

4. The filtering device of claim 3, wherein the filter circuit is configured to set the first cutoff frequency based on the first amplification value, the second amplification value, the third amplification value, and the second cutoff frequency.

5. The filtering device of claim 4, wherein the filter circuit is configured to set the first cutoff frequency, based on the second amplification value being −1, proportional to the second cutoff frequency and inversely proportional to the first amplification value and the third amplification value.

6. The filtering device of claim 1, wherein the filter circuit is configured to set the first cutoff frequency, based on the filter circuit being an nth-order filter, “n” being a natural number greater than or equal to 1, inversely proportional to an nth root of the first amplification value.

7. The filtering device of claim 4, wherein the filter circuit is configured to set the first cutoff frequency, based on the filter circuit being an nth-order filter, “n” being a natural number greater than or equal to 1, and the second amplification value being −1, proportional to the second cutoff frequency, inversely proportional to an nth root of the first amplification value, and inversely proportional to an nth root the third amplification value.

8. The filtering device of claim 3, wherein the feedback circuit is configured to set a gain of the filtering device based on the first amplification value, the second amplification value, and the third amplification value.

9. The filtering device of claim 8, wherein the feedback circuit is configured to set, based on the second amplification value being −1, the gain of the filtering device based on the third amplification value.

10. A filtering device for passing a frequency component above a first cutoff frequency in an input signal, the filtering device comprising:
an amplification circuit configured to generate an amplification signal based on the input signal, a first feedback signal, and a second feedback signal;
a filter circuit configured to generate an output signal by passing a frequency component above a second cutoff frequency higher than the first cutoff frequency in the amplification signal; and
a feedback circuit configured to generate the first feedback signal and the second feedback signal by amplifying the output signal,
the filter circuit configured to set the first cutoff frequency based on a gain of the amplification circuit, a gain of the filter circuit, and the second cutoff frequency.

11. The filtering device of claim 10, wherein the amplification circuit comprises:
a first amplifier configured to generate an intermediate signal by amplifying, by a first amplification value, a result of subtracting the second feedback signal from the input signal; and
a second amplifier configured to generate the amplification signal by subtracting the first feedback signal from the intermediate signal.

12. The filtering device of claim 10, wherein the feedback circuit comprises:
a first feedback amplification circuit configured to generate the first feedback signal by amplifying the output signal by a second amplification value; and
a second feedback amplification circuit configured to generate the second feedback signal by amplifying the output signal by a third amplification value.

13. The filtering device of claim 12, wherein the filter circuit is configured to set the first cutoff frequency based on the gain of the amplification circuit, the gain of the filter circuit, the second amplification value, the third amplification value, and the second cutoff frequency.

14. The filtering device of claim 13, wherein the filter circuit is configured to set the first cutoff frequency, based on the second amplification value being −1, based on the gain of the amplification circuit, the gain of the filter circuit, the third amplification value, and the second cutoff frequency.

15. The filtering device of claim 12, wherein the feedback circuit is configured to set a gain of the filtering device based on the gain of the amplification circuit, the gain of the filter circuit, the second amplification value, and the third amplification value.

16. The filtering device of claim 15, wherein the feedback circuit is configured to set, based on the second amplification value being −1, the gain of the filtering device based on the third amplification value.

17. A radar sensor comprising:
a signal generator configured to generate a transmission signal;
a transmission amplifier configured to amplify the transmission signal;
a transmission antenna configured to radiate the transmission signal;
a reception antenna configured to receive, as a reception signal, a reflection signal returned as a result of reflection of the transmission signal from an object;
a reception amplifier configured to amplify the reception signal; and
a signal processor configured to perform signal processing on the reception signal,
the signal processor comprising
a filtering device configured to generate an output signal by passing a frequency component above a first cutoff frequency in an input signal generated based on the reception signal,
the filtering device comprising
an amplification circuit configured to generate an amplification signal based on the input signal, a first feedback signal, and a second feedback signal;
a filter circuit configured to generate an output signal by passing a frequency component above a second cutoff frequency higher than the first cutoff frequency in the amplification signal; and
a feedback circuit configured to generate the first feedback signal and the second feedback signal by amplifying the output signal,
the filtering device configured to set the first cutoff frequency based on a first amplification value corresponding to a gain of the amplification circuit and the second cutoff frequency.

18. The radar sensor of claim 17, wherein the amplification circuit comprises:
a first subtractor configured to generate a first intermediate signal by subtracting the second feedback signal from the input signal;
a first amplifier configured to generate a second intermediate signal by amplifying the first intermediate signal by the first amplification value; and
a second subtractor configured to generate the amplification signal by subtracting the first feedback signal from the second intermediate signal.

19. The radar sensor of claim 17, wherein the feedback circuit comprises:
a second amplifier configured to generate the first feedback signal by amplifying the output signal by a second amplification value; and
a third amplifier configured to generate the second feedback signal by amplifying the output signal by a third amplification value.

20. The radar sensor of claim 19, wherein the filtering device is configured to set the first cutoff frequency proportional to the second cutoff frequency and inversely proportional to the first amplification value, the second amplification value, and the third amplification value.

21.-22. (canceled)
